(19) United States
(12) Patent Application Publication
(10) Pub. No.: US 2018/0046072 A1
(43) Pub. Date: Feb. 15, 2018

(54) AUTOMATED FULL-CHIP DESIGN SPACE SAMPLING USING UNSUPERVISED MACHINE LEARNING

(71) Applicant: GLOBALFOUNDRIES Inc., Grand Cayman (KY)

(72) Inventor: Andrey Lutich, Dresden (DE)

(21) Appl. No.: 15/233,232

(22) Filed: Aug. 10, 2016

(51) Int. Cl. G03F 1/36; G06F 17/50; G06N 99/00

(52) U.S. Cl. CPC G03F 1/36; G06N 99/005; G06F 17/5081; G06F 17/5045

(57) ABSTRACT

An illustrative method includes reading in a layout as current layout to be analyzed, splitting the current layout into n sub-layouts, where n is a positive integer, such that each sub-layout fits into a predetermined memory, performing a clustering step for each of the sub-layouts, including scanning the respective sub-layout for features and converting each sub-layout into a set of feature vectors defining individual patterns, searching each set of feature vectors for clusters having predetermined cluster parameters, and selecting m characteristic representatives of patterns from each cluster, where m is a positive integer, merging the characteristic representatives of each of the n sub-layouts into a new single layout, searching the characteristic representatives discovered for the individual sub-layouts for clusters having predetermined cluster parameters, selecting M characteristic representatives of patterns from each cluster, where M is a positive integer, and outputting the characteristic representatives of patterns.

### BACKGROUND OF THE INVENTION

### 1. Field of the Invention

Generally, the present disclosure relates to the manufacturing of integrated circuits, and, more particularly, to the creation of photomasks for use in photolithographic processes.

### 2. Description of the Related Art

Integrated circuits typically include a large number of circuit elements which include, in particular, field effect transistors. Other types of circuit elements which may be present in integrated circuits include capacitors, diodes and resistors. The circuit elements in an integrated circuit may be electrically connected by means of electrically conductive metal lines formed in a dielectric material, for example, by means of damascene techniques. The electrically conductive metal lines may be provided in a plurality of interconnect layers that are stacked on top of each other above a substrate in and on which the circuit elements are formed. Metal lines in different interconnect layers may be electrically connected with each other by means of contact vias that are filled with metal.

Due to the complexity of modern integrated circuits, in the design of integrated circuits, automated design techniques are typically employed.

The design of an integrated circuit typically employs a number of steps. These steps may include the creation of a user specification that defines the functionality of the integrated circuit. The user specification may be the basis for the creation of a register transfer level description that models the integrated circuit in terms of a flow of signals between hardware registers and logical operations performed on those signals. The register transfer level description of the integrated circuit may then be used for the physical design of the integrated circuit, wherein a layout of the integrated circuit is created. The thus-created layout may be the basis for the formation of photomasks that may be employed for patterning materials in the manufacturing of the integrated circuit by means of photolithography processes.

In a photolithography process, a photomask pattern is projected on to a layer of a photoresist that is provided over a semiconductor structure. Portions of the photoresist are irradiated with radiation that is used for projecting the photomask pattern on to the photoresist. Other portions of the photoresist are not irradiated, wherein the pattern of irradiated portions of the photoresist and portions of the photoresist that are not irradiated depends on a pattern of printing features provided on the photomask.

Thereafter, the photoresist may be developed. Depending on whether a negative or a positive photoresist is used, in the development process, either the non-irradiated portions or the irradiated portions of the photoresist are dissolved in a developer and, thus, removed from the semiconductor structure.

Thereafter, processes for patterning the semiconductor structure, which, in particular, may include one or more etch processes, may be performed, using the portions of the photoresist remaining on the semiconductor structure as a photoresist etch mask. Thus, features in accordance with the created layout of the integrated circuit may be formed on the semiconductor structure.

In the formation of small features in semiconductor structures, resolution enhancement techniques may be employed. These may include optical proximity correction (OPC), off-axis illumination (OAI), sub-resolution assist features (SRAF) or phase shift masks (PSM). However, lithographic hotspots, for example pinching (i.e., violation of minimal width conditions) or bridging (violation of minimum distance conditions), cannot be completely eliminated with these techniques. It has been shown that such hotspots may be pattern dependent.

Despite these problems, adequate design sampling and understanding of possible design options is essential for development and maintenance of the manufacturing process in general and OPC components and methods in particular. Some areas where adequate design space sampling is absolutely necessary are given in the following list: (1) site selection for process changes verification and monitoring; (2) site selection for lithography illumination optimization; (3) site selection for model building and verification; (4) site selection for SRAF and OPC recipe optimization; and (5) finding design spots that are very different from others, i.e., finding anomalies.

Well-known site selection strategies for either resolution enhancement technology (RET) and/or OPC development or fabrication process monitoring may rely on:
(i) Manually analyzing the design. However this approach may suffer from not being comprehensive, being too generic and it is far from reality of today's needs of fabrication processes.
(ii) Results of design rule checking (DRC) and/or optical rule checking (ORC). However, this approach is hardly applicable to sampling. This approach typically only addresses worst case scenarios. It is typically convoluted with model accuracy. Furthermore, a lot of prior knowledge of the underlying models used will be needed, as well as on assumptions for DRC etc.
(iii) Experiences of an individual design engineer with respect to the design space. However, this approach appears hardly reproducible. The risk of introducing systematic errors is quite high. Further, it may be uncertain if an optimum selection may be found.
(iv) Image parameter space analysis. This approach typically covers optics only, it requires input such as models, sites, etc. which have to enter the analysis after having been preselected with some other method.
(v) Eventually, failures found in hardware may be also taken into account. However, this typically comes too late, and is likely to be unacceptably expensive.
(vi) Algorithms such as support vector machine (SVM), neural networks, regression models, principal component analysis, etc. These approaches typically require a priori knowledge of weak spots/hot spots to train these algorithms and in addition are often not applicable to large databases. For example, for using these algorithms, it is typically very difficult, if not impossible, to classify large layouts with 10⁹ or even more patterns.

In fact, the following estimate indicates that this limit may be even lower. Typically computational complexity is on the order of: O(n²)-O(n³). However, the number of patterns layouts typically grows as n². Therefore datasets larger than 10⁵ at one shot appears hardly feasible.

In view of the above-discussed problems, the present disclosure provides an alternative approach. The present disclosure discloses methods which may be applied to sampling full chip physical designing layouts in semiconductor manufacturing.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative method disclosed herein includes a method that may include: (i) reading in a layout as current layout to be analyzed; (ii) splitting the current layout into n sub-layouts where n is a positive integer such that each sub-layout fits into a predetermined memory; (iii) performing a clustering step for each of the sub-layouts, including (a) scanning the respective sub-layout for features and converting each sub-layout into a set of feature vectors defining individual patterns, (b) searching each set of feature vectors for clusters having predetermined cluster parameters, and (c) selecting m characteristic representatives of patterns from each cluster, where m is a positive integer; (iv) merging the characteristic representatives of each of the n sub-layouts into a new single layout; (v) in case the new single layout of step (iv) does not fit into the predetermined memory, assign the new single layout as the current layout and continue with step (ii); (vi) searching the characteristic representatives discovered for the individual sub-layouts for clusters having predetermined cluster parameters; (vii) selecting M characteristic representatives of patterns from each cluster, where M is a positive integer; and (viii) outputting the characteristic representatives of patterns.

Furthermore, a computer-implemented method running on a computer system comprising a plurality of machines is disclosed. In one illustrative embodiment, the computer-implemented method may include: (i) reading in a layout from an external storage memory as current layout to be analyzed; (ii) splitting the current layout into n sub-layouts, where n is a positive integer, such that each sub-layout fits into a predetermined memory of a single machine; (iii) performing a clustering step for each of the sub-layouts, including (a) scanning the respective sub-layout for features and converting each sub-layout into a set of feature vectors defining individual patterns, (b) searching each set of feature vectors for clusters having predetermined cluster parameters, and (c) selecting m characteristic representatives of patterns from each cluster, where m is a positive integer; (iv) merging the characteristic representatives of each of the n sub-layouts into a new single layout; (v) in case the new single layout of step (iv). does not fit into the predetermined memory of a single machine, assign the new single layout as the current layout and continue with step (ii); (vi) searching the characteristic representatives discovered for the individual sub-layouts for clusters having predetermined cluster parameters; (vii) selecting M characteristic representatives of patterns from each cluster, where M is a positive integer; and (viii) outputting the characteristic representatives of patterns into a layout file.

The disclosed methods may also include unsupervised machine learning (UML) methods. Thereby, datasets to be explored and to be discovered may be analyzed with little or even no a priori knowledge. These methods may be capable of analyzing a layout of an entire chip. Moreover, these methods may be applied to any layer.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates splitting a layout into sub-layouts;

FIG. 2 symbolically indicates a sequence of iterations including splitting, clustering, merging of layout data;

FIG. 3 schematically indicates extracting features using one example;

FIG. 4 schematically indicates an example of representatives of clusters;

FIG. 5 schematically indicates calculations for clustering;

FIG. 6 indicates a flow of steps of the method; and

FIGS. 7A-7C schematically indicates a gallery and a site-list of results.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

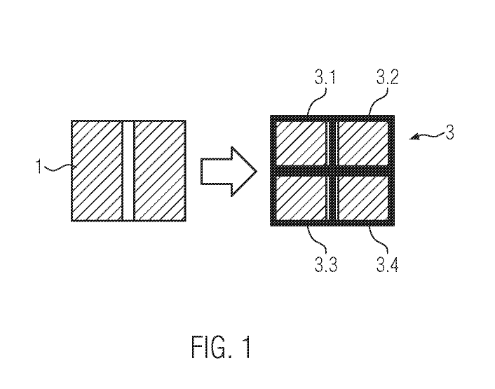

FIG. 1 illustrates a layout 1 to be analyzed. The layout 1 to be analyzed may be a design, a layout of a chip and/or may comprise layers of such a layout. The layout 1 may be read from a storage medium (not shown), such as a hard disk, optical disk, etc. The layout 1 may be given in a table-like/tuple-like or matrix representation. The tuple or matrix may be multi-dimensional. FIG. 1 schematically illustrates splitting a layout into sub-layouts. As indicated by the arrow, FIG. 1 further illustrates splitting the single layout 1 into a plurality of sub-layouts 3. The sub-layouts 3 may also be termed as tiles. For exemplary purposes only, FIG. 1 illustrates splitting the single layout 1 into n sub-layouts 3.1, 3.2, 3.3 and 3.4, with n=4. However, it should be understood that n may be an integer larger than 1, and in particular, the number of sub-layouts/tiles may be smaller or larger than 4. Subsequently, the n sub-layouts are each analyzed or treated on the same footing. For the sake of simplicity, it should be understood that each of the n sub-layouts, e.g., in FIG. 1, sub-layouts 3.1, 3.2, 3.3, 3.4, may have the same size. It should also be understood that this is not a strict requirement and it may be possible to have groups of sub-layouts with different sizes than other sub-layouts. This, however, may require, again, some a priori knowledge of how sparsely some areas of the single layout 1 are populated.

FIG. 1 brings up the question on how many sub-layouts may be needed in the splitting step. Here, the original, single layout to be analyzed needs to be read in. This may be done on a computing system. The computing system may be a multi-node or multi-machine computing system. The size of the original single layout may either be known from the storage medium, hard disk, optical disk, cloud, etc. or may be determined on the fly when read in. For example, the size of the single layout may be several to several tens of Gigabytes. The computing system, for example, will know the size of available memory of a single machine/node. Typically, the available memory of a single machine/node is less than the physical memory of the machine, since the single machine needs some memory for other tasks. A typical size of the available memory may be two Gigabyte or four Gigabyte of memory, but other values of sizes may be possible. From this, the computing system may be able to estimate the size of one of the sub-layouts, i.e., one of the tiles the single layout 1 may be split into.

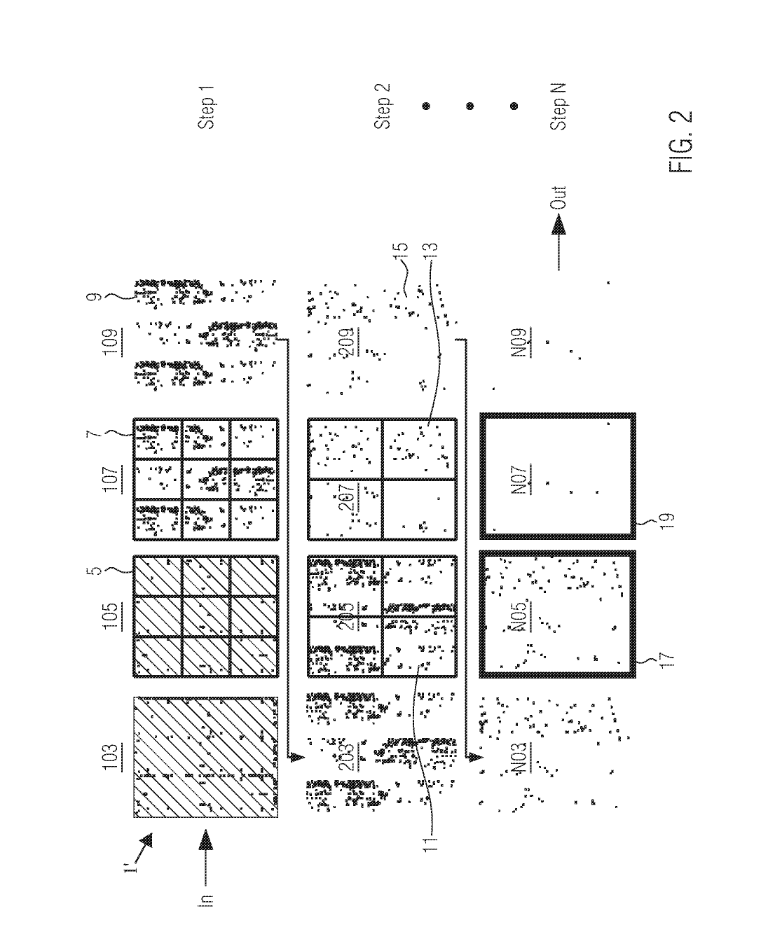

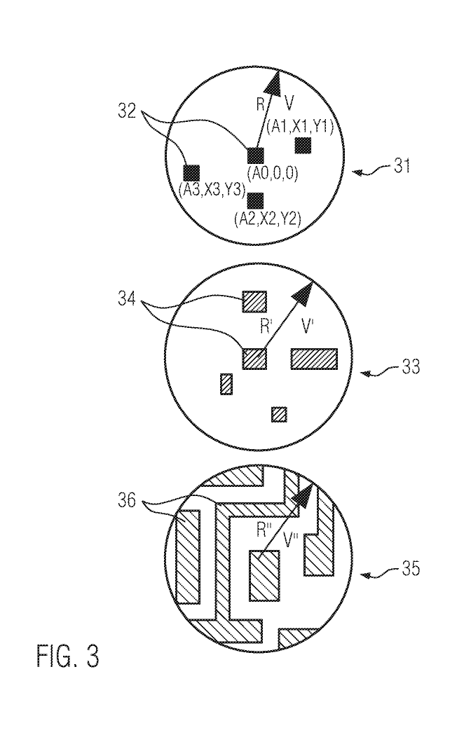

FIG. 2 symbolically indicates a sequence of iterations for analyzing a single layout 1′. The single layout 1′ may be similar to the layout 1 of FIG. 1. FIG. 2 symbolically indicates reading in the single layout from an input source “In”. FIG. 2 then schematically indicates four steps termed i03, i05, i07, i09, with i=1, 2, . . . N, depicted horizontally from left to right and steps Step i, I=1, 2, . . . , N, depicted from top to bottom. For exemplary purposes only, only the steps for i=1, i=2 and i=N are shown. The steps in horizontal direction may be explained as follows. In step 103, the layout 1′ is shown as read in from the input source “In”. For example, the input source may be a database, a storage medium, a cloud or the like. Step 105 indicates splitting the initial single layout into sub-layouts, denoted by 5. Here, for exemplary purposes only, nine sub-layouts/tiles are shown. As indicated already for FIG. 1, the sub-layouts 5 may or may not have the same size. Step 107 indicates that within each sub-layout of the nine sub-layouts 5, clustering is performed. Details of clustering will be further discussed with regard to FIGS. 3-6. The clustering 107 symbolically and—here for exemplary purposes—visibly indicates that the very fine structured data of the single layout 1′ which is also present in the sub-layouts 5 of step 105 will now become sparser by identifying clusters and patterns, denoted by 7. Here, clusters and patterns 7 are represented by some representatives of each cluster such that not the entire data of a cluster needs to be kept. This way, the amount of data which originated from the single layout 1′ is now reduced. Step 109 illustrates a merging of the representatives from the sub-layouts/tiles 7 so as to obtain, again, a new single layout 9, which now is sparser than the original layout 1′.

FIG. 2 further illustrates that the new single layout 9 of step 109 is transferred to the 2^{nd} row of FIG. 2, i.e., Step 2 in the downward vertical direction. Thus, step 203 illustrates the same new single layout 9 as in step 109. Following the sequential steps, or in a recursive way, step 205 indicates splitting the new single layout 9 into sub-layouts denoted by 11. For exemplary purposes only, four sub-layouts 11 are illustrated, but it should be understood that a different number of sub-layouts 11 may be chosen. Similar to step 107, step 207 indicates clustering performed within each of the sub-layouts/tiles 11 of step 205 which are now denoted by 13. Eventually, step 209 illustrates merging of the representatives from the sub-layouts/tiles 13, so as to obtain, again, a new single layout 15 of the second row step, i.e., Step 2.

As indicated in FIG. 2, the iteration continues for the N^{th} row, where, for the sake of illustration and simplicity, the new single layout 15 is copied to step N03, or in other words N=3. Here, step N05 indicates the splitting into just one sub-layout 17. Step N07 indicates the clustering of the sub-layout 17 so as to become clusters and patterns of the sub-layout 17, denoted by 19. Eventually the merging step N09 provides the result of the iteration, which then may be output to an output means indicate by “Out”, this may be a database, a storage medium, a cloud or the like.

As indicated already with respect to FIG. 1, the criterion to perform another step of the iteration or recursion is to determine whether or not the result of the merging in steps 109, 209 . . . N09 fits into the memory of a single machine/node. Then, the final clustering step is performed before the result is output. Details of the clustering will be discussed with regard to FIGS. 3-6.

FIG. 3 schematically indicates extracting features from data of a sub-layout/tile. Here, using one example, details of data of at least a part of a sub-layout 31 are denoted by 32. A feature vector V having a length/norm R, which may be interpreted as a radius of a circle 31, is illustrated in FIG. 3. In other words, FIG. 3 illustrates examples/types of the physical layout patterns that are considered as structural elements to be analyzed by the various methods described here. For performing this analysis, these patterns should be converted into a vector form, called feature vector. One feature vector describes one pattern. Feature vectors can be constructed in different ways. A non-exhaustive list of examples include (i) list of distances of all polygons from the center of the pattern with their dimensions/surface areas within radius R, (ii) list of coordinates of all polygons with their dimensions/surface areas within radius R, (iii) list of polygon edges, or (iv) list of coordinates of all vertices in the most general case. There may be other construct of the feature vector V. As an example, for via-like layers, a sub-layout 31 of FIG. 3 indicates the coordinates of the four polygons, e.g., squares, as (A0, 0, 0), (A1, X1, Y1), (A2, X2, Y2), (A3, X3, Y3). Then a feature vector V may be given by:

V=(A0,A1,X1,Y1,A2,X2,Y2,A3,X3,Y3) or

V=(A0,A1,D1,A2,D2,A3,D3) with Dₙ²=Xₙ²+Yₙ², where n=1,2,3.

In 33, due to clustering and selecting of representatives of 32, larger structures 34 are illustrated and a vector V′ with its length R′ is shown, as well. Still further in the iteration process, 35 illustrates even larger clusters and patterns 36 within the radius R″ of the vector V″. Thus, by finding clusters and selecting one or few representatives of the clusters, larger structures can be presented.

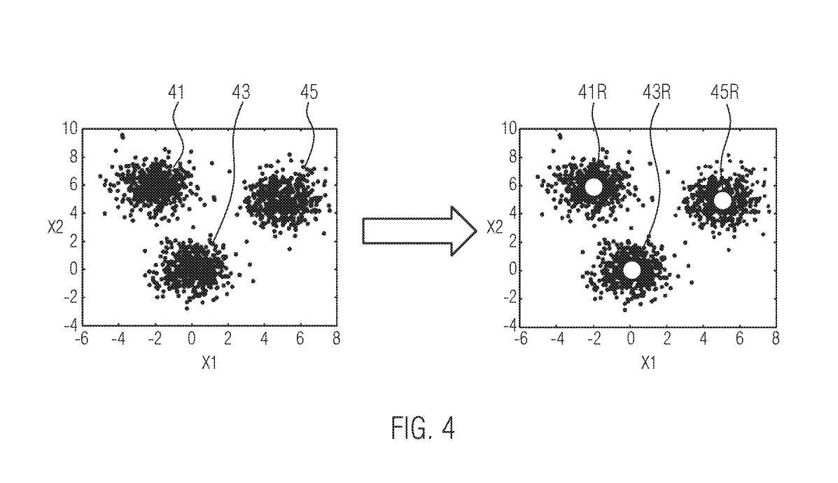

FIG. 4 schematically indicates an example of representatives of clusters. Here, for exemplary purposes only, three clusters 41, 43, 45 are illustrated. The three clusters may be different from each other. As indicated by the arrow, on the right-hand side, representatives 41R, 43R and 45R are determined for each of the clusters, respectively. The representatives may coincide with a center of gravity of the respective cluster. Varying, i.e., shifting, the location/coordinates of the respective representative may support finding the optimum location of the representative. Whereas, in this case, each cluster has one representative, it may be necessary to select more than one representative per cluster.

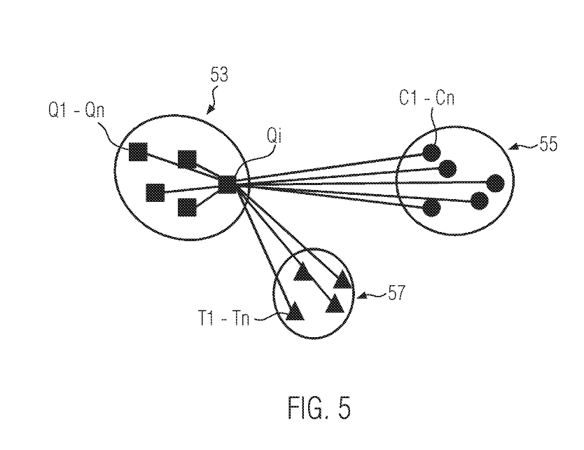

FIG. 5 schematically indicates calculations for clustering according to an example. FIG. 5 illustrates three clusters denoted 53, 55 and 57. Cluster 53 comprises elements/data Q1 . . . Qn, where n is a positive integer. Likewise, cluster 55 comprises elements C1 . . . Cn, and cluster 57 comprises elements T1 . . . Tn. It should be understood that the clusters 53, 55 and 57 may have differing numbers of elements per cluster. FIG. 5 illustrates that, for one element Qi among the Qn elements of cluster 53, distances to every other element of cluster 53 and also to every element of the other clusters 55 and 57 is calculated. The result is stored in memory. The process is repeated for all elements of all clusters. This indicates that it may be computationally quite expensive. The benefit, however, is that once the distances have been calculated, they may serve as an indicator for selecting the feature vectors and representatives (see FIGS. 3 and 4).

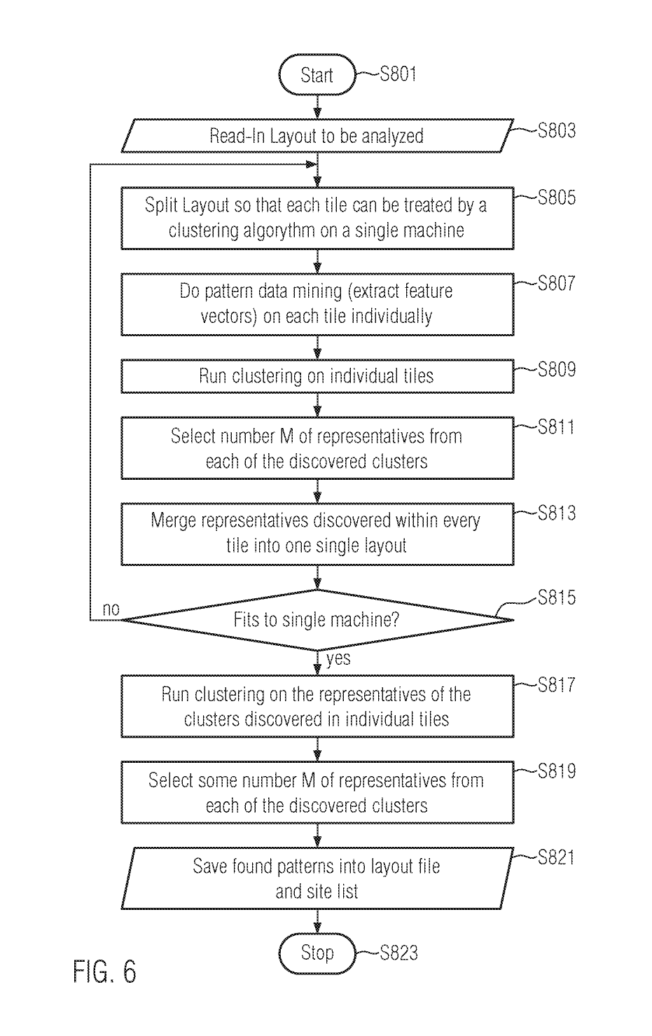

FIG. 6 indicates a flow of steps of one illustrative embodiment of an illustrative method disclosed herein. This method, as for the discussion of FIGS. 1-5, may be implemented on a computer system. This may also be compared to the symbolical illustration of FIG. 2.

The start of the method is indicated by S801. In step S803, a predetermined layout is read in to become the layout to be analyzed. This layout may be read from a database, a storage medium, a cloud, etc. This layout may also be provided from specific third party layout designers. In step S805, the layout is split into sub-layouts or tiles (see FIGS. 1 and 2). For example, the layout may be split into n sub-layouts/tiles, where n is a positive integer larger than one. This step may include determining, during the read in of the initial layout, the size of the layout and estimating or predetermining the effectively available memory of a single machine/node. Typically, the number of machines will be at least as large as the number of sub-layouts.

Step S805 is followed by a so-called data mining step S807. In this step, each sub-layout is treated separately. It should be understood that, for the sake of speed, the n machines may operate substantially in parallel. Data mining should be understood as searching for and extracting of features. The data of the layout is scanned through and converted into a set of feature vectors (FIGS. 4 and 5). A feature vector may be, for example, denoted by X=(X1, X2 . . . Xl), where l is a positive integer and X1 . . . Xl are the elements or coordinates of the feature vector. For example, these coordinates may be distances, angles, radii, areas of individual pattern sub-components, overlay, enclosure or any other metrics. A feature vector may have 20-30 coordinates, i.e., l=20-30, but other values may be possible. As an example, for via-like layers of a layout, extracted patterns may be centered on vias and the following format of feature vectors may be used: X=(A0, {A1, D1}, {A2, D2} . . . {An, Dn}), where A0 denotes the area of the via/contact itself, and pairs {Ax, Dx} are the area and distance of/to the neighboring vias, sorted in ascending order.

After having converted the data of the layout into feature vectors, the clustering follows in step S809. Data clustering is one of the types of unsupervised machine learning problems. It targets discovering data structure within data. Clustering operates in/on the space of feature vectors: X=(X1, X2 . . . Xl). It may be used to assign individual feature vectors to clusters. Therefore, the design space of each tile may be sampled by selecting characteristic representatives of each cluster (FIGS. 4 and 5). Clustering may be very computationally and memory expansive because it typically calculates and stores dissimilarity between all objects in the dataset.

As indicated in FIG. 6, the clustering is followed by step S811 which indicates selecting some number M, where M is a positive integer of representatives from each of the discovered clusters of step S809. As indicated in FIG. 4, there may be at least one representative per cluster. It may be possible to also have more than one representative per cluster.

Step S813 comprises merging of the representatives discovered and assigned in step S811 into one single layout. It is understood that this single layout is different from the initial layout of step S803. The layout in step S813 is sparser or coarser.

Step S815 checks whether or not the single layout of step S813 fits to a single machine/node of the computer system, meaning that it should fit into the effectively available memory of the machine. If it does not fit into it, the process starts another iteration and uses the single layout of step S813 as the new input layout for step S805. This new input layout is then—again split into sub-layouts.

If the check of step S815 is affirmative, the method proceeds with step S817. The clustering on the representatives is run one more time. Again, a number of M representatives may be selected, where M is a positive integer. These representatives may denote the discovered clusters or patterns (step S819).

Eventually, the patterns which were found and which are indicated by their representatives are output into a layout file and/or a site-list in step S8212. The method concludes with step S823.

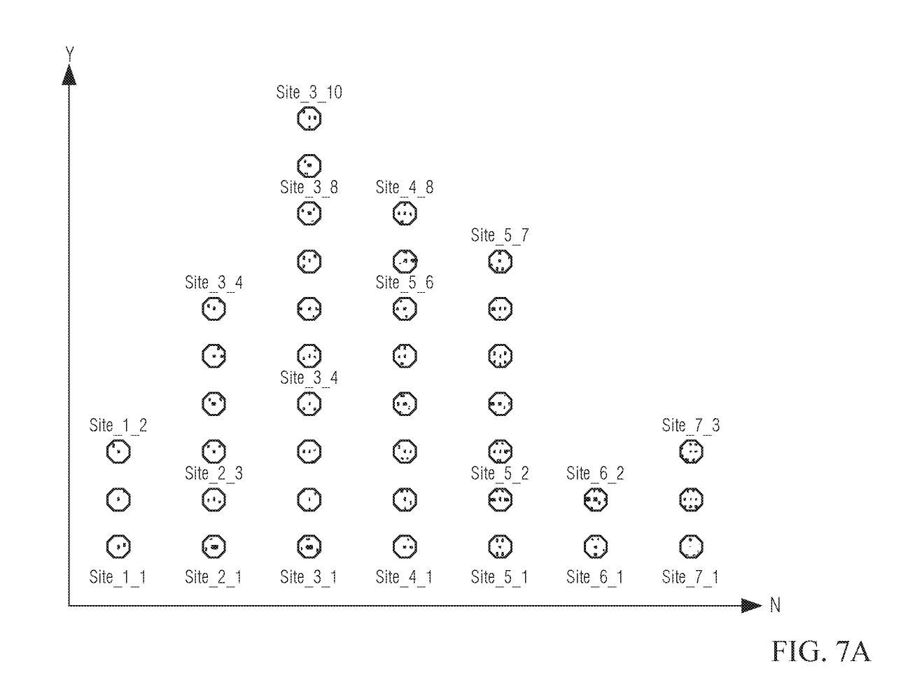

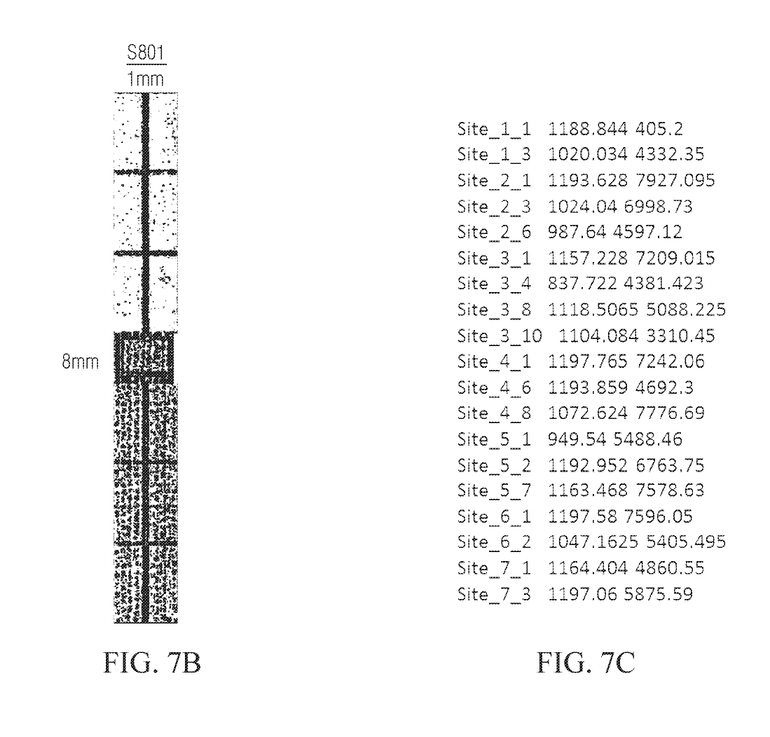

FIGS. 7A-7C schematically indicate a gallery and a site-list of results output in step S823. In a table-like depiction, FIG. 7A illustrates an axis giving the number N of neighbors of a site and an axis Y indicating how often the respective pattern was instantiated. The patterns are denoted by “Site_N_Y”, where N and Y are the respective coordinates. Thus sites “Site_1_1”, “Site_2_1” . . . “Site_7_1” are, in this example, the patterns which are most seldom instantiated, whereas, for this example, “Site_3_10” is most often instantiated. FIG. 7B illustrates, in a view of a full chip, locations of the patterns of the layout analyzed. FIG. 7C outputs the results as a site-list in text format. From this, the patterns and ultimately problematic regions may be read, directly.

The above-described method has been applied successfully to 22 nm design space sampling for patterning process screening. The method served so as to confirm the process has sufficient margin. It also has been applied successfully to 22 nm design space sampling for resist benchmarking and comparing various model performances, so as to discover locations having insufficient margin post etching steps.

This method may be used for selecting representative design sites from incoming designs and using the output of said characteristic representatives of patterns for at least one of determining process changes, monitoring optical proximity correction performance monitoring and controlling optical proximity correction development.

The above-described method may be implemented by using any appropriate programming environment, e.g., MATLAB® or similar environments, but may also be implemented using a higher programming language.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method, comprising:
(i) reading in a layout as current layout to be analyzed;
(ii) splitting said current layout into n sub-layouts, where n is a positive integer larger than or equal to 1, such that each sub-layout fits into a predetermined memory;
(iii) performing a clustering step for each of said sub-layouts, comprising:
(a) scanning the respective sub-layout for features and converting each sub-layout into a set of feature vectors defining individual patterns;
(b) searching each set of feature vectors for clusters having predetermined cluster parameters; and
(c) selecting m characteristic representatives of patterns from each cluster, where m is a positive integer larger than or equal to 1;
(iv) merging said characteristic representatives of each of said n sub-layouts into a new single layout;
(v) in case said new single layout of step (iv) does not fit into said predetermined memory, assign said new single layout as said current layout and continue with step (ii);
(vi) searching said characteristic representatives discovered for said individual sub-layouts for clusters having predetermined cluster parameters;
(vii) selecting M characteristic representatives of patterns from each cluster, where M is a positive integer larger than or equal to 1; and
(viii) outputting said characteristic representatives of patterns.

2. The method of claim 1, further comprising using said output of characteristic representatives of patterns for at least one of determining process changes, monitoring optical proximity correction performance monitoring and controlling optical proximity correction development.

3. The method of claim 1, wherein all of said n-sub-layouts have a same size.

4. The method of claim 1, wherein said features comprise one or more of distances, angles, areas of individual sub components, areas of overlay and enclosures.

5. The method of claim 1, wherein, if said layout to be analyzed comprises via-like layers, individual patterns are centered on vias; wherein feature vectors X centered on vias are of the format X=(A0, {A1, D1}, {A2, D2} . . . {An, Dn}), where A0 denotes an area of the via itself, pairs {Ax, Dx} denote area and distance of/to the neighboring vias, respectively, sorted in ascending order.

6. The method of claim 1, wherein said clustering step assigns individual feature vectors to respective clusters.

7. The method of claim 1, further comprising the step of visualizing characteristic representatives as gallery and/or as site list, wherein coordinates of said individual patterns are saved into said site list.

8. The method of claim 1, wherein said clustering step comprises calculating dissimilarity between all data of the respective sub-layout.

9. The method of claim 1, wherein said clustering step comprises calculating a distance from each object to every other object.

10. The method of claim 9, wherein said clustering step comprises calculating said distance using Euclidean coordinates and a corresponding norm.

11. The method of claim 1, wherein selecting characteristic representatives comprises calculating and varying a center of gravity of a cluster.

12. The method of claim 1, further comprising confirming that each of said determined patterns has a sufficient margin with respect to a predefined process window.

13. A computer-implemented method running on a computer system comprising a plurality of machines, the computer-implemented method comprising:
(i) reading in a layout from an external storage memory as current layout to be analyzed;
(ii) splitting said current layout into n sub-layouts, where n is a positive integer larger than or equal to 1, such that each sub-layout fits into a predetermined memory of a single machine;
(iii) performing a clustering step for each of said sub-layouts, comprising:
(a) scanning the respective sub-layout for features and converting each sub-layout into a set of feature vectors defining individual patterns;
(b) searching each set of feature vectors for clusters having predetermined cluster parameters; and
(c) selecting m characteristic representatives of patterns from each cluster, where m is a positive integer larger than or equal to 1;
(iv) merging said characteristic representatives of each of said n sub-layouts into a new single layout;
(v) in case said new single layout of step (iv) does not fit into said predetermined memory of a single machine, assign said new single layout as said current layout and continue with step (ii);
(vi) searching said characteristic representatives discovered for the individual sub-layouts for clusters having predetermined cluster parameters;
(vii) selecting M characteristic representatives of patterns from each cluster, where M is a positive integer larger than or equal to 1; and
(viii) outputting said characteristic representatives of patterns into a layout file.

14. The computer-implemented method of claim 13, further comprising using said output of characteristic representatives of patterns for at least one of determining process changes, monitoring optical proximity correction performance monitoring and controlling optical proximity correction development.

15. The computer-implemented method of claim 13, wherein all of said plurality of machines are equal.

16. The computer-implemented method of claim 13, wherein all of said n-sub-layouts have a same size.

17. The computer-implemented method of claim 13, wherein said features comprise one or more of distances, angles, areas of individual sub components, areas of overlay, and enclosures.

18. The computer-implemented method of claim 13, wherein said clustering step comprises calculating dissimilarity between all data of the respective sub-layout.

19. The computer-implemented method of claim 13, wherein said predetermined memory is at least a subset of the entire memory of a single machine.

20. The computer-implemented method of claim 13, further comprising confirming that each of said determined patterns has a sufficient margin with respect to a predefined process window.
